(19) United States
(12) Patent Application Publication
(10) Pub. No.: US 2026/0324122 A1
(43) Pub. Date: Oct. 15, 2026

(54) METHOD FOR PACKAGING AN OPTICAL PROXIMITY SENSOR

(71) Applicant: STMicroelectronics International N.V., Geneva (CH)

(72) Inventor: Jing-En LUAN, Singapore (SG)

(73) Assignee: STMicroelectronics International N.V., Geneva (CH)

(21) Appl. No.: 19/176,472

(22) Filed: Apr. 11, 2025

(51) Int. Cl. H10F 55/00; H10F 71/00; H10F 77/00; H10F 77/50

(52) U.S. Cl. CPC H10F 55/18; H10F 71/136; H10F 77/50; H10F 77/933

(57) ABSTRACT

A covered optical integrated circuit device is mounted to each device mounting area of a substrate panel. The covered optical integrated circuit device includes an integrated circuit die with a front connection pad and an optical integrated circuit region covered by a transparent optical element body that does not cover the front connection pad. A bonding wire connects the front connection pad to a corresponding front wire bonding pad of the substrate panel. An opaque material is molded to encapsulate the covered optical integrated circuit devices, except at portions of the upper surface of the transparent optical element body, and the bonding wires and cover an upper surface of the substrate panel where the covered optical integrated circuit devices are not mounted. A cutting is performed between device mounting areas to singulate the molded product into optical packages.

### TECHNICAL FIELD

The present disclosure generally relates to integrated circuit packaging and, in particular, to a method for packaging an optical proximity sensor and the resulting optical proximity sensor package.

### BACKGROUND

Electronic sensor technology is currently being incorporated into many consumer products, including automobiles, appliances, and mobile devices such as smart phones. Electronic micro-sensor devices can be used to detect environmental conditions such as temperature, humidity, rainfall, sounds, and the like. Such devices can also be used to detect modes of operation of consumer appliances in which they are installed, such as the orientation of a smart phone, use of voice commands, ambient light, and the like. Micro-sensors offer many advantages due to their size, reliability, and low cost. As electronic micro-sensors become smaller and less expensive, they are in higher demand.

One example of an electronic micro-sensor is an optical proximity sensor that detects the presence of nearby objects without a need for physical contact. Some optical proximity sensors emit a light beam that is reflected from a target object. The reflected light beam is then captured by the proximity sensor and compared with the emitted beam or with an ambient light level to detect changes that can yield information about the target object. One specific implementation of such a sensor is known to those skilled in the art as a Time of Flight (ToF) sensor that measures a time difference between emission of the light beam and return of the light beam reflected by the target to calculate a distance to the target.

Reference is now made to FIG. 1 which shows a cross-sectional view of a conventional ToF optical sensor package 100. The package 100 includes a substrate 104 formed, for example, by a printed circuit board including front die attach pads 106a, front wire bonding pads 106b, rear connection pads 108 (for example, forming a land grid array (LGA) structure) and an electrical connection network 110 (formed, for example, using micro-via structures) for electrically connecting the front die attach pads 106a and front wire bonding pads 106b to the rear connection pads. A sensor integrated circuit die 112 is mounted at the front surface of the substrate 104 to one of the front die attach pads 106a. Front bonding pads of the sensor integrated circuit die 112 are electrically connected to front wire bonding pads 106b of the substrate 104 by bonding wires. The sensor integrated circuit die 112 includes a photosensitive region 116. An emitter integrated circuit die 114 is also mounted at the front surface of the substrate 104 to another one of the front die attach pads 106a. One or more front bonding pads at the front surface of the sensor integrated circuit die 112 are electrically connected to one or more other front wire bonding pads 106b of the substrate 104 by bonding wires. The emitter integrated circuit die 114 includes a photoemission region 120. A cap 124 is mounted to the substrate 104. The cap 124 is made of an opaque material and includes a peripheral side wall and a front wall. Distal ends of the peripheral side wall are mounted to the substrate 104 using a suitable adhesive. Openings are provided in the front wall generally vertically aligned with the locations of the photosensitive region 116 for the sensor integrated circuit die 112 and the photoemission region 120 of the emitter integrated circuit die 114. An interior wall of the cap is positioned between the photosensitive region 116 of the sensor integrated circuit die 112 and the photoemission region 120 for the emitter integrated circuit die 114. Each of the openings in the front wall of the cap 124 is covered with a transparent optical element 128 (such as, for example, including a lens and perhaps a filter) mounted by a suitable adhesive to an inside surface of the front wall of the cap 124 (or within the opening itself).

In operation, light is emitted from the photoemission region 120 of the emitter integrated circuit die 114 in response to control signaling generated by the sensor integrated circuit die 112. This light propagates through the transparent optical element 128a to outside of the package 100 to illuminate a target object. Light reflected by the target object returns to the package 100, passes through the transparent optical element 128b, and is detected by the photosensitive region 116. The sensor integrated circuit die 112 measures the difference in time between emission of the light by the emitter integrated circuit die 114 and sensing of the returned light reflected by the target object by the first photosensitive region 116, and then calculates the distance from package 100 to the target object as a function of the measured difference in time.

There is a need in the art for improved packaging of the sensor integrated circuit die 112 and the emitter integrated circuit die 114. Such improved packaging should provide, for example, a smaller form factor in all dimensions. Such improved packaging should further support a lower manufacturing cost suited for high volume production. Still further, a stiffer package resilient to warpage and capable of supporting more circuit components, with a higher robustness, is desirable.

### SUMMARY

In an embodiment, a method comprises: at each of a plurality of device mounting areas for a substrate panel, mounting at least one covered optical integrated circuit device, where said covered optical integrated circuit device comprises an integrated circuit die with a front connection pad and an optical integrated circuit region and a transparent optical element body that covers the optical integrated circuit region but does not cover the front connection pad; electrically connecting the front connection pad of each integrated circuit die to a corresponding front wire bonding pad of the substrate panel using a bonding wire; placing the substrate panel with mounted and wirebonded covered optical integrated circuit devices within a cavity of a two-part mold which includes a mold projection aligned (vertically) with a location of each transparent optical element body; injecting an opaque material into the cavity of the two-part mold to encapsulate the covered optical integrated circuit devices and the bonding wires and cover an upper surface of the substrate panel where the covered optical integrated circuit devices are not mounted; removing the opaque material encapsulated substrate panel from the two-part mold; and singulating the opaque material encapsulated substrate panel by cutting between device mounting areas to produce a plurality of optical packages.

In an embodiment, an optical package comprises: a substrate panel including a device mounting area, wherein said device mounting area includes a front wire bonding pad; a covered optical integrated circuit device mounted to the device mounting area, where said covered optical integrated circuit device comprises an integrated circuit die with a front connection pad and an optical integrated circuit region and a transparent optical element body that covers the optical integrated circuit region but does not cover the front connection pad; a bonding wire electrically connecting the front connection pad of the covered optical integrated circuit device to the front wire bonding pad of the substrate panel; and an opaque material body encapsulating the covered optical integrated circuit device and the bonding wire and covering an upper surface of the substrate panel where the covered optical integrated circuit device is not mounted; wherein the opaque material body includes an opening exposing an upper surface of the transparent optical element body and aligned with the optical integrated circuit region.

### BRIEF DESCRIPTION OF THE DRAWINGS

For a better understanding of the embodiments, reference will now be made by way of example only to the accompanying figures in which:

FIG. 1 is a cross-sectional view of a conventional time of flight (ToF) optical sensor package;

FIG. 2 is a cross-sectional view of an optical sensor package;

FIG. 3 is a cross-sectional view of an optical sensor package;

FIGS. 4A-4F show steps of a method for manufacturing a covered optical integrated circuit device for the optical sensor package of FIG. 3; and

FIGS. 5A-5F show steps of a method for manufacturing the optical sensor package of FIG. 3 using the covered optical integrated circuit devices made from the process of FIGS. 4A-4F.

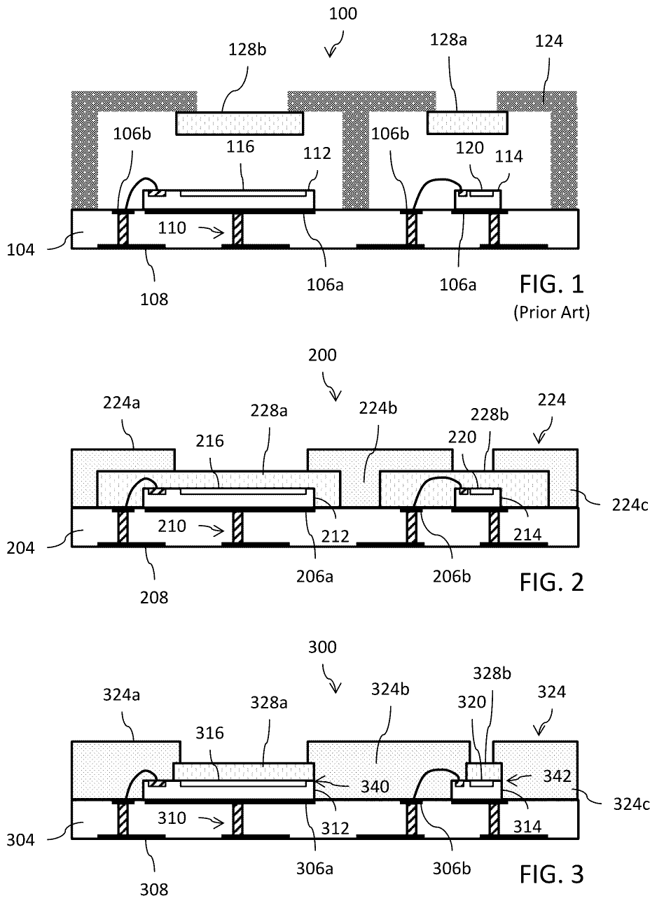

### DETAILED DESCRIPTION

In the following description, certain specific details are set forth in order to provide a thorough understanding of various aspects of the disclosed subject matter. However, the disclosed subject matter may be practiced without these specific details. In some instances, well-known structures and methods of semiconductor processing comprising embodiments of the subject matter disclosed herein have not been described in detail to avoid obscuring the descriptions of other aspects of the present disclosure.

Reference is now made to FIG. 2 which shows a cross-sectional view of an optical sensor package 200. The package 200 includes a substrate 204 formed, for example, by a printed circuit board including front die attach pads 206a, front wire bonding pads 206b, rear connection pads 208 (for example, forming a land grid array (LGA) structure) and an electrical connection network 210 (formed, for example, using micro-via structures) for electrically connecting the front die attach pads 206a and front wire bonding pads 206b to the rear connection pads. A sensor integrated circuit die 212 is mounted at the front surface of the substrate 204 to one of the front die attach pads 206a. Front bonding pads of the sensor integrated circuit die 212 are electrically connected to front wire bonding pads 206b of the substrate 204 by bonding wires. The sensor integrated circuit die 212 includes a photosensitive region 216. An emitter integrated circuit die 214 is also mounted at the front surface of the substrate 204 to another one of the front die attach pads 206a. One or more front bonding pads at the front surface of the emitter integrated circuit die 214 are electrically connected to one or more other front wire bonding pads 206b of the substrate 204 by bonding wires. The emitter integrated circuit die 214 includes a photoemission region 220. A first transparent optical element body 228a encapsulates the sensor integrated circuit die 212 (at the top side and lateral sides) and further encapsulates its bonding wires. The first transparent optical element body 228a further covers an area of the front surface of the substrate 204 where the sensor integrated circuit die 212 is mounted, and the front die attach pads 206a and front wire bonding pads 206b of the sensor integrated circuit die 212 are also covered. A second transparent optical element body 228b encapsulates the emitter integrated circuit die 214 (at the top side and lateral sides) and further encapsulates its bonding wires. The second transparent optical element body 228b further covers an area of the front surface of the substrate 204 where the emitter integrated circuit die 214 is mounted, and the front die attach pads 206a and front wire bonding pads 206b for the emitter integrated circuit die 214 are also covered. An opaque body 224 encapsulates (laterally and on top of) the first and second transparent optical element bodies 228a, 228b and further covers an area of the front surface of the substrate 204 where the first and second transparent optical element bodies 228a, 228b are not located. The opaque body 224 includes openings in a front wall portion 224a exposing a portion of the upper surfaces of the transparent optical element bodies 228 that are generally vertically aligned with the locations of the photosensitive region 216 for the sensor integrated circuit die 212 and the photoemission region 220 of the emitter integrated circuit die 214. The opaque body 224 includes an interior wall portion 224b positioned between the photosensitive region 216 of the sensor integrated circuit die 212 and the photoemission region 220 for the emitter integrated circuit die 214. Side wall portions 224c of the opaque body 224 delimit the outer edge of the package 200.

In operation, light is emitted from the photoemission region 220 of the emitter integrated circuit die 214 in response to control signaling generated external to the package and/or under the control of the sensor integrated circuit die 212. This light propagates through the transparent optical element 228b to outside of the package 200 to illuminate a target object. Light reflected by the target object returns to the package 200, passes through the transparent optical element 228a, and is detected by the photosensitive region 216. The sensor integrated circuit die 212 measures the difference in time between emission of the light by the emitter integrated circuit die 214 and sensing of the returned light reflected by the target object by the first photosensitive region 216, and then calculates the distance from package 200 to the target object as a function of the measured difference in time.

Reference is now made to FIG. 3 which shows a cross-sectional view of an optical sensor package 300. The package 300 includes a substrate 304 formed, for example, by a printed circuit board including front die attach pads 306a, front wire bonding pads 306b, rear connection pads 308 (for example, forming a land grid array (LGA) structure) and an electrical connection network 310 (formed, for example, using micro-via structures) for electrically connecting the front die attach pads 306a, front wire bonding pads 306b to the rear connection pads. A sensor integrated circuit die 312 is mounted at the front surface of the substrate 304 to one of the front die attach pads 306a. Front bonding pads of the sensor integrated circuit die 312 are electrically connected to front wire bonding pads 306b of the substrate 304 by bonding wires. The sensor integrated circuit die 312 includes a photosensitive region 316. An emitter integrated circuit die 314 is also mounted at the front surface of the substrate 304 to another one of the front die attach pads 306a. One or more front bonding pads at the front surface of the emitter integrated circuit die 314 are electrically connected to one or more other front wire bonding pads 306b of the substrate 304 by bonding wires. The emitter integrated circuit die 314 includes a photoemission region 320. A first transparent optical element body 328a is mounted to an upper surface of the sensor integrated circuit die 312 and covers the photosensitive region 316 of the sensor integrated circuit die 312 (but notably does not cover the front bonding pads of the sensor integrated circuit die 312). This first transparent optical element body 328a has one or more peripheral edges coinciding with a peripheral edge of the sensor integrated circuit die 312 (this being generally indicated for one pair of coincident (i.e., vertically aligned) peripheral edges at reference 340) except where the front bonding pads of the sensor integrated circuit die 312 are left uncovered. A second transparent optical element body 328b is mounted to the upper surface of the emitter integrated circuit die 314 and covers the photoemission region 320 of the emitter integrated circuit die 314 (but notably does not cover the front bonding pads of the emitter integrated circuit die 314). This second transparent optical element body 328b has one or more peripheral edges coinciding with a peripheral edge of the emitter integrated circuit die 314 (this being generally indicated for one pair of coincident (i.e., vertically aligned) peripheral edges at reference 342) except where the front bonding pads of the emitter integrated circuit die 314 are left uncovered. An opaque body 324 encapsulates (laterally and on top of) the first and second transparent optical element bodies 328a, 328b, as well as encapsulates (laterally and on top of) the sensor integrated circuit die 312 and emitter integrated circuit die 314, and further encapsulates the bonding wires. This opaque body 324 further covers an area of the front surface of the substrate 304 where the sensor integrated circuit die 312 and emitter integrated circuit die 314 are not located. The opaque body 324 includes openings in a front wall portion 324a that expose portions of the upper surface of the transparent optical element bodies 328 and are generally vertically aligned with the locations of the photosensitive region 316 for the sensor integrated circuit die 312 and the photoemission region 320 of the emitter integrated circuit die 314. The opaque body 324 includes an interior wall portion 324b positioned between the photosensitive region 316 of the sensor integrated circuit die 312 and the photoemission region 320 for the emitter integrated circuit die 314. Side wall portions 324c of the opaque body 324 delimit the outer edge of the package 300.

In operation, light is emitted from the photoemission region 320 of the emitter integrated circuit die 314 in response to control signaling generated external to the package and/or under the control of the sensor integrated circuit die 312. This light propagates through the transparent optical element 328b to outside of the package 300 to illuminate a target object. Light reflected by the target object returns to the package 300, passes through the transparent optical element 328a, and is detected by the photosensitive region 316. The sensor integrated circuit die 312 measures the difference in time between emission of the light by the emitter integrated circuit die 314 and sensing of the returned light reflected by the target object by the first photosensitive region 316, and then calculates the distance from package 300 to the target object as a function of the measured difference in time.

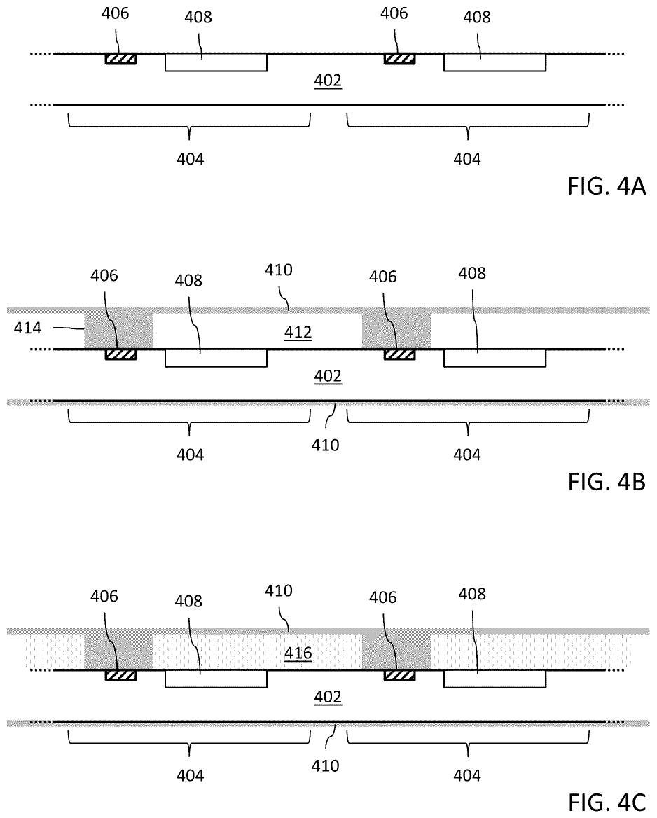

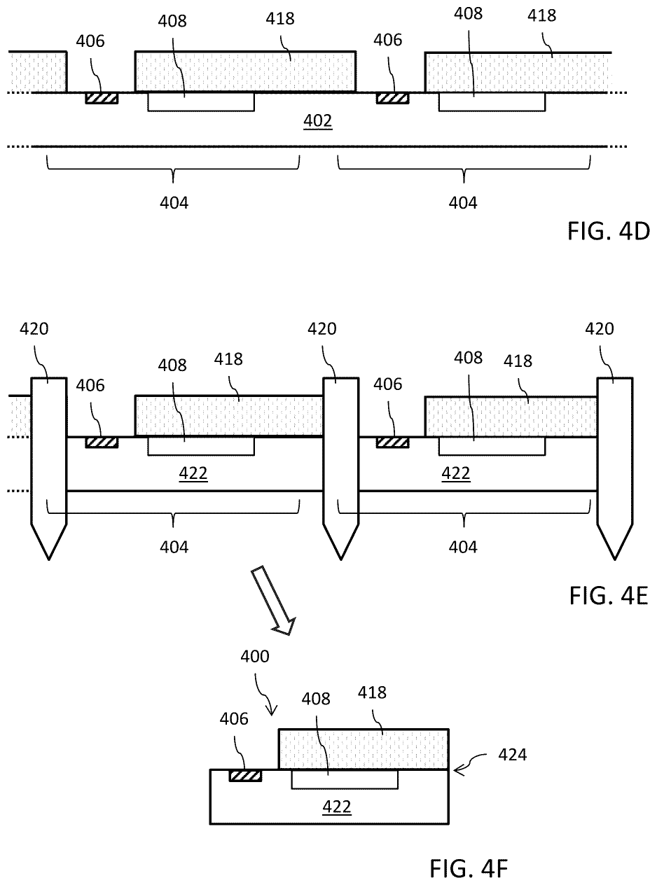

Reference is now made to FIG. 4A-4F which show steps of a method of manufacturing a covered optical integrated circuit device 400 which is used in the package 300 of FIG. 3. In this context, the covered optical integrated circuit device 400 may comprise the sensor integrated circuit die 312 covered by the first transparent optical element body 328a and/or the emitter integrated circuit die 314 covered by the second transparent optical element body 328b, as shown in FIG. 3.

FIG. 4A—a silicon integrated circuit substrate wafer 402 is fabricated using conventional techniques well known to those skilled in the art. The wafer includes a plurality of integrated circuit areas 404 which are each fabricated at wafer level to include front connection pads 406 and an optical integrated circuit region 408. The front connection pads 406 correspond, for example, to the front bonding pads for the sensor integrated circuit die 312 and/or the emitter integrated circuit die 314 of FIG. 3. The optical integrated circuit regions 408 correspond, for example, to the photosensitive region 316 of the sensor integrated circuit die 312 and/or the photoemission region 320 for the emitter integrated circuit die 314 of FIG. 3.

FIG. 4B—the silicon integrated circuit substrate wafer 402 is then placed within the cavity 410 of a two-part mold 412. The top half of the mold 412 includes mold projections 414 aligned (vertically) with the locations of the front connection pads 406. When the mold 412 is closed over the silicon integrated circuit substrate wafer 402, the mold projections 414 cover the front connection pads 406.

FIG. 4C—a transparent material 416 is then injected in the cavity 412 of the mold 410 and allowed to cure. The transparent material 416 covers the optical integrated circuit regions 408 as well as portions of the upper surface of the wafer 402 which are not protected by the mold projections 414.

FIG. 4D—the silicon integrated circuit substrate wafer 402, with molded transparent material 416 forming transparent optical element bodies 418 which cover the optical integrated circuit regions 408 and upper surfaces of the wafer 402 but leave the front connection pads 406 uncovered, is then removed from the mold 410.

FIG. 4E—a singulation process using a cutting tool 420 dices the wafer 402 with the molded transparent material 416 into a plurality of covered optical integrated circuit devices 400. Each singulated device 400 as shown in FIG. 4F includes an integrated circuit die 422 with one or more front connection pads 406 and an optical integrated circuit region 408 and further includes a transparent optical element body 418 which covers the optical integrated circuit region 408 but does not cover the one or more front connection pads 406. Furthermore, as a result of the singulation process of FIG. 4E, peripheral edges of the transparent optical element body 418 coincide with peripheral edges of the die 422 (this being generally indicated for one pair of coincident (i.e., vertical aligned) peripheral edges at reference 424) except where the front bonding pads of the die 422 are left uncovered. The integrated circuit die 422 may correspond to the die 312, 314 and the transparent optical element body 418 may correspond to the transparent optical element body 328a, 328b as shown in FIG. 3.

It will be understood that different wafers may be provided with optical integrated circuit regions corresponding to photosensitive regions 316 for the making of sensor integrated circuit dies 312 and corresponding photoemission regions 320 for the making of emitter integrated circuit dies 314, with the process of FIGS. 4A-4F being separately performed on those wafers to produce singulated devices 400 as shown in FIG. 4F for the sensor integrated circuit dies 312 and the emitter integrated circuit dies 314.

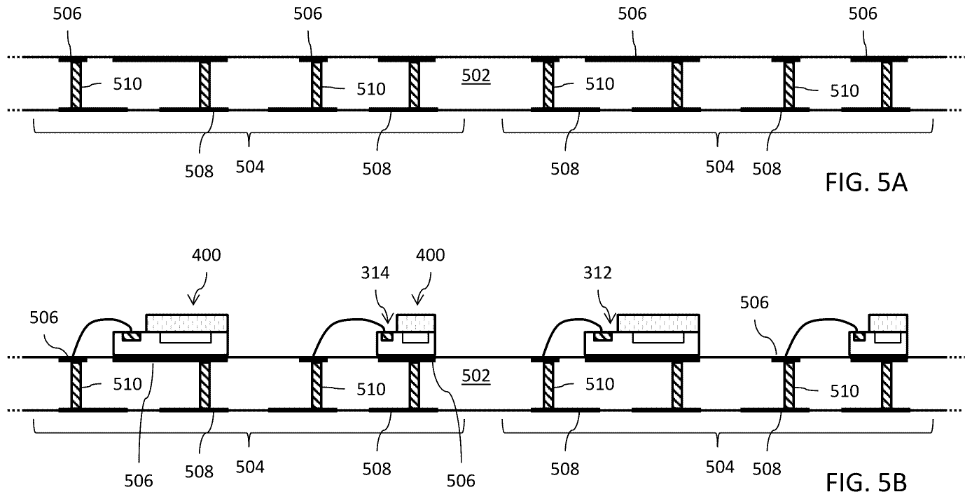

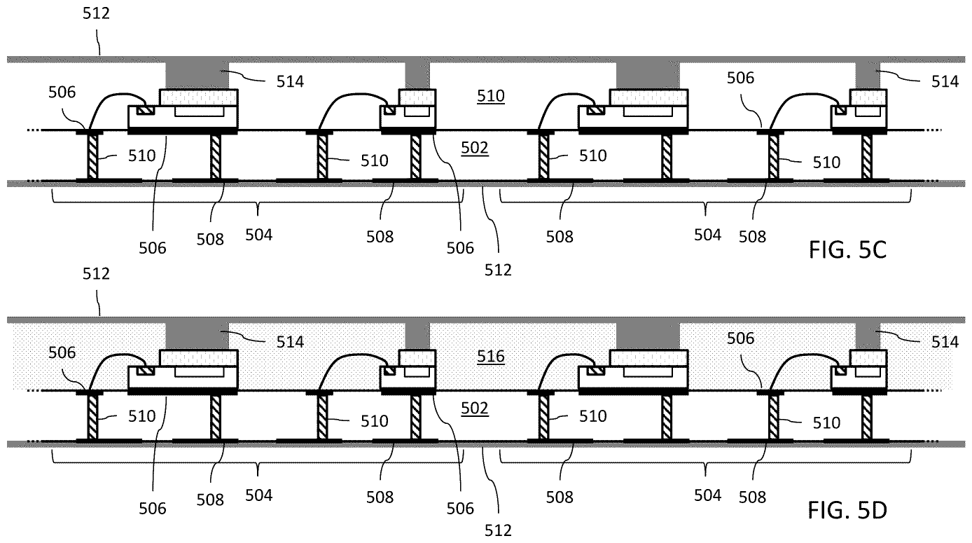

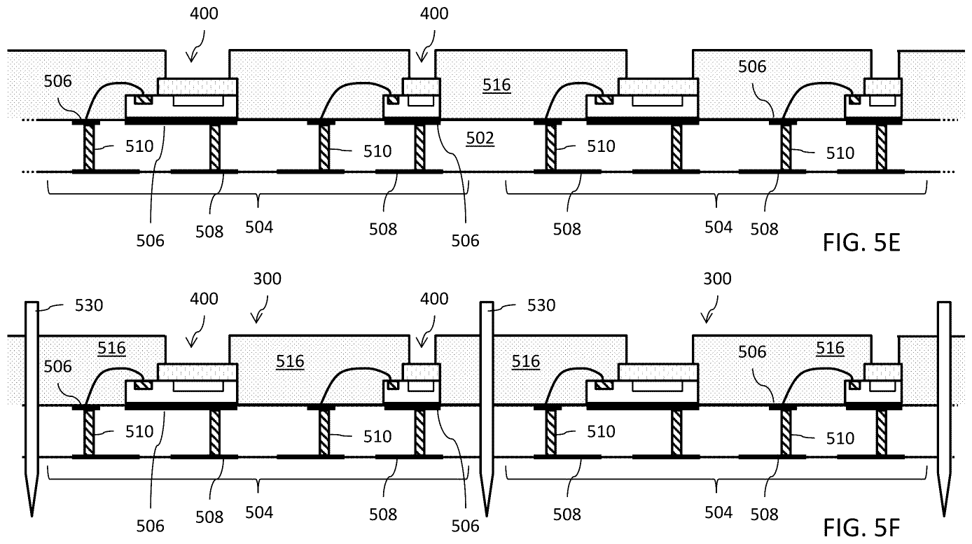

Reference is now made to FIGS. 5A-5F which show steps of a method for manufacturing the optical sensor package 300 of FIG. 3 using the covered optical integrated circuit devices 400 made from the process of FIGS. 4A-4F.

FIG. 5A—a substrate panel 502 is fabricated using conventional techniques well known to those skilled in the art. The panel 502 includes a plurality of device mounting areas 504 to which one or more devices, such as the covered optical integrated circuit devices 400 of FIG. 4F, are mounted. The panel 502 is formed by an insulating substate layer that includes front electrically conductive pads 506, rear electrically conductive pads 508, and electrically conductive vias 510 which electrically connect the front electrically conductive pads 506 to the rear electrically conductive pads 508. The panel 502 may be of printed circuit board (PCB) type. The front electrically conductive pads 506 correspond, for example, to the front die attach pads 306a and front wire bonding pads 306b as shown in FIG. 3. The rear electrically conductive pads 508 correspond, for example, to the rear connection pads 308 (arranged in a land grid array (LGA) format) as shown in FIG. 3. The electrically conductive vias 510 correspond, for example, to the electrical connection network 310 as shown in FIG. 3.

FIG. 5B—one or more covered optical integrated circuit devices 400 (see, FIG. 4F, as made for example using the process of FIGS. 4A-4E) are mounted to the substrate panel 502 at each device mounting area 504. In particular, each covered optical integrated circuit device 400 is mounted to a corresponding front electrically conductive pad 506 which provides a front die attach pad 306a. Each mounted covered optical integrated circuit devices 400 is then electrically connected through bonding wires to corresponding front electrically conductive pads 506 which provide front wire bonding pads 306b. In a preferred implementation, a first covered optical integrated circuit device 400 with a sensor integrated circuit die 312 and a second covered optical integrated circuit device 400 with an emitter integrated circuit die 314 are mounted at each device mounting area 504.

FIG. 5C—the substrate panel 502 with the mounted and wirebond connected covered optical integrated circuit devices 400 is then placed within the cavity 510 of a two-part mold 512. The top half of the mold 512 includes mold projections 514 aligned (vertically) with the locations of the transparent optical element bodies 418 of the devices 400 (and more specifically aligned (vertically) with the locations of the photosensitive regions 316 and photoemission regions 320 of the dies 312 and 314, respectively).

FIG. 5D—an opaque material 516 is then injected in the cavity 512 of the mold 510 and allowed to cure. The opaque material 516 encapsulates (laterally and on top of)the transparent optical element bodies 418, integrated circuit die 422 and bonding wires for each of the mounted devices 400 and covers the upper surface of the substrate panel 502 as well as the exposed front electrically conductive pads 506 at each device mounting area 504. When the mold 512 is closed over the substrate panel 502 with the mounted and wirebonded covered optical integrated circuit devices 400, the mold projections 514 cover a portion of the upper surface of each transparent optical element body 418.

FIG. 5E—after curing, the opaque material 516 encapsulated substrate panel 502 with the mounted and wirebonded covered optical integrated circuit devices 400 is then removed from the mold 510. Openings through the opaque material 516 that expose the upper surfaces of the transparent optical element bodies 418 are provided at each position where the mold projections 514 were located.

FIG. 5F—a singulation process using a cutting tool 530 dices the opaque material 516 encapsulated substrate panel 502 with the mounted and wirebonded covered optical integrated circuit devices 400 into a plurality of optical sensor packages 300. Each singulated package 300 is shown in FIG. 3.

In a preferred implementation, the package 200, 300 is a component of an electronic device such as a smart phone. More specifically, the package 200, 300 may, for example, be integrated into or with a touch screen of the electronic device.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. A method, comprising:
at each of a plurality of device mounting areas for a substrate panel, mounting at least one covered optical integrated circuit device, where said covered optical integrated circuit device comprises an integrated circuit die with a front connection pad and an optical integrated circuit region and a transparent optical element body that covers the optical integrated circuit region but does not cover the front connection pad;
electrically connecting the front connection pad of each integrated circuit die to a corresponding front wire bonding pad of the substrate panel using a bonding wire;
placing the substrate panel with mounted and wirebonded covered optical integrated circuit devices within a cavity of a two-part mold which includes a mold projection aligned with a location of each transparent optical element body;
injecting an opaque material into the cavity of the two-part mold to encapsulate the covered optical integrated circuit devices and the bonding wires and cover an upper surface of the substrate panel where the covered optical integrated circuit devices are not mounted;
removing the opaque material encapsulated substrate panel from the two-part mold; and
singulating the opaque material encapsulated substrate panel by cutting between device mounting areas to produce a plurality of optical packages.

2. The method of claim 1, wherein the covered optical integrated circuit device has a photoemission region for the optical integrated circuit region.

3. The method of claim 2, wherein the mold projection is aligned with the photoemission region.

4. The method of claim 1, wherein the covered optical integrated circuit device has a photosensitive region for the optical integrated circuit region.

5. The method of claim 4, wherein the mold projection is aligned with the photosensitive region.

6. The method of claim 1, further comprising making the covered optical integrated circuit device by:
providing an integrated circuit substrate wafer that includes a plurality of integrated circuit areas which each include the front connection pad and the optical integrated circuit region;
placing the integrated circuit substrate wafer within a cavity of a further two-part mold which includes a further mold projection aligned with a location of each front connection pad, wherein said further mold projection does not cover the optical integrated circuit region;
injecting a transparent material into the cavity of the further two-part mold to cover the optical integrated circuit regions as well as portions of an upper surface of the integrated circuit substrate wafer which are not protected by the further mold projections;
removing the transparent material covered integrated circuit substrate wafer from the further two-part mold; and
singulating the transparent material covered integrated circuit substrate wafer by cutting between integrated circuit areas to produce a plurality of covered optical integrated circuit devices, each covered optical integrated circuit device including the integrated circuit die with the front connection pad and the optical integrated circuit region with the transparent optical element body covering the optical integrated circuit region but not covering the front connection pad.

7. The method of claim 6, wherein peripheral edges of the transparent optical element body coincide with peripheral edges of the integrated circuit die except where the front bonding pads of the integrated circuit die are not covered by the transparent optical element body.

8. An optical package made by the method of claim 1.

9. An optical package, comprising:
a substrate panel including a device mounting area, wherein said device mounting area includes a front wire bonding pad;
a covered optical integrated circuit device mounted to the device mounting area, where said covered optical integrated circuit device comprises an integrated circuit die with a front connection pad and an optical integrated circuit region and a transparent optical element body that covers the optical integrated circuit region but does not cover the front connection pad;
a bonding wire electrically connecting the front connection pad of the covered optical integrated circuit device to the front wire bonding pad of the substrate panel; and
an opaque material body encapsulating the covered optical integrated circuit device and the bonding wire and covering an upper surface of the substrate panel where the covered optical integrated circuit device is not mounted;
wherein the opaque material body includes an opening exposing an upper surface of the transparent optical element body and aligned with the optical integrated circuit region.

10. The optical package of claim 9, wherein the optical integrated circuit region of the covered optical integrated circuit device is a photoemission region.

11. The optical package of claim 9, wherein the optical integrated circuit region of the covered optical integrated circuit device is a photosensitive region.

12. The optical package of claim 9, wherein peripheral edges of the transparent optical element body coincide with peripheral edges of the integrated circuit die except where the front bonding pads of the integrated circuit die are not covered by the transparent optical element body.
